(19) United States
(12) Patent Application Publication
(10) Pub. No.: US 2026/0282430 A1
(43) Pub. Date: Sep. 17, 2026

(54) SEMICONDUCTOR DEVICE AND METHOD FOR FABRICATING THE SAME

(71) Applicant: UNITED MICROELECTRONICS CORP., Hsin-Chu City (TW)

(72) Inventors: Ching-Wen Hung, Tainan City (TW); Yan-Zung Wang, Tainan City (TW); Chun-Hsien Lin, Tainan City (TW)

(73) Assignee: UNITED MICROELECTRONICS CORP., Hsin-Chu City (TW)

(21) Appl. No.: 19/178,841

(22) Filed: Apr. 14, 2025

(30) Foreign Application Priority Data
Mar. 17, 2025 (TW) 114109839

(51) Int. Cl. H10D 30/66; H10D 30/01; H10D 62/832; H10D 64/00

(52) U.S. Cl. CPC H10D 30/66; H10D 30/0291; H10D 62/8325; H10D 64/111

(57) ABSTRACT

A method for fabricating a semiconductor device includes the steps of first forming a gate material layer on a substrate, patterning the gate material layer to form a first gate structure, a second gate structure, and a dummy gate between the first gate structure and the second gate structure, forming an interlayer dielectric (ILD) layer on the first gate structure, the second gate structure, and the dummy gate, forming an opening in the ILD layer to expose the dummy gate, and then forming a source electrode in the opening to connect to the dummy gate.

### BACKGROUND OF THE INVENTION

### 1. Field of the Invention

The invention relates to a semiconductor device and fabrication method thereof, and more particularly to a silicon carbide (SiC) metal oxide semiconductor field effect transistor (MOSFET) and method for fabricating the same.

### 2. Description of the Prior Art

Typical power semiconductor device includes insulated gate bipolar transistors (IGBTs) and metal oxide semiconductor field effect transistor (MOSFET) device, within which silicon carbide (SiC) MOSFET has critical breakdown strength, can operate at much higher temperatures, provide higher current density, and support higher switching frequencies.

Although semiconductor device such as SiC MOSFET has the above-mentioned advantages, the gate oxide of silicon carbide (SiC) MOSFET is especially vulnerable on voltage spiking induced on gate bias during operation and electrostatic discharge (ESD) stress because of thinner gate oxide thickness and lower oxide quality. In conventional approach, additional devices may be added for protecting gate oxide from voltage overshot and ESD stress. However, extra space is usually required for accommodating these devices, which ultimately increases cell pitch of the entire device. Since conventional approach for fabricating SiC MOSFETs still exist numerous problems, how to come up with a novel approach for fabricating SiC MOSFETs to resolve the above issues has become an important task in this field.

### SUMMARY OF THE INVENTION

According to an embodiment of the present invention, a method for fabricating a semiconductor device includes the steps of first forming a gate material layer on a substrate, patterning the gate material layer to form a first gate structure, a second gate structure, and a dummy gate between the first gate structure and the second gate structure, forming an interlayer dielectric (ILD) layer on the first gate structure, the second gate structure, and the dummy gate, forming an opening in the ILD layer to expose the dummy gate, and then forming a source electrode in the opening to connect to the dummy gate.

According to another aspect of the present invention, a semiconductor device includes a first gate structure, a second gate structure, and a dummy gate between the first gate structure and the second gate structure on a substrate, an interlayer dielectric (ILD) layer on the first gate structure, the second gate structure, and the dummy gate, and a source electrode on the ILD layer and directly connected to the dummy gate.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-6 illustrate a method for fabricating a semiconductor device according to an embodiment of the present invention.

### DETAILED DESCRIPTION

Although specific configurations and arrangements are discussed, it should be understood that this is done for illustrative purposes only. A person skilled in the pertinent art will recognize that other configurations and arrangements can be used without departing from the spirit and scope of the present disclosure. It will be apparent to a person skilled in the pertinent art that the present disclosure can also be employed in a variety of other applications.

It is noted that references in the specification to “one embodiment,” “an embodiment,” “an example embodiment,” “some embodiments,” etc., indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of a person skilled in the pertinent art to effect such feature, structure or characteristic in connection with other embodiments whether or not explicitly described.

In general, terminology may be understood at least in part from usage in context. For example, the term “one or more” as used herein, depending at least in part upon context, may be used to describe any feature, structure, or characteristic in a singular sense or may be used to describe combinations of features, structures or characteristics in a plural sense. Similarly, terms, such as “a,” “an,” or “the,” again, may be understood to convey a singular usage or to convey a plural usage, depending at least in part upon context.

It should be readily understood that the meaning of “on,” “above,” and “over” in the present disclosure should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something).

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the term “substrate” refers to a material onto which subsequent material layers are added. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically non-conductive material, such as a glass, a plastic, or a sapphire wafer.

As used herein, the term “layer” refers to a material portion including a region with a thickness. A layer can extend over the entirety of an underlying or overlying structure, or may have an extent less than the extent of an underlying or overlying structure. Further, a layer can be a region of a homogeneous or inhomogeneous continuous structure that has a thickness less than the thickness of the continuous structure. For example, a layer can be located between any pair of horizontal planes between, or at, a top surface and a bottom surface of the continuous structure. A layer can extend horizontally, vertically, and/or along a tapered surface. A substrate can be a layer, can include one or more layers therein, and/or can have one or more layer thereupon, thereabove, and/or therebelow. A layer can include multiple layers. For example, an interconnect layer can include one or more conductor and contact layers (in which contacts, interconnect lines, and/or vias are formed) and one or more dielectric layers.

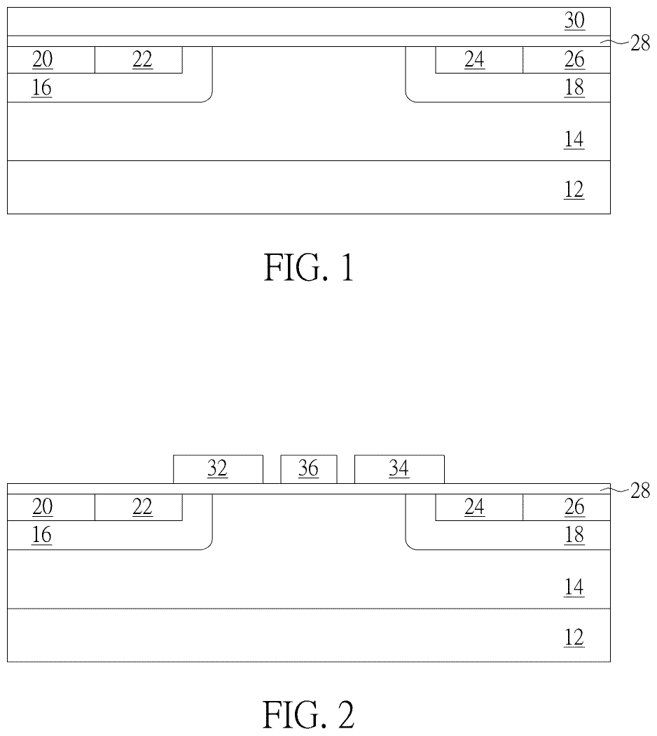

Referring to FIGS. 1-6, FIGS. 1-6 illustrate a method for fabricating a semiconductor device according to an embodiment of the present invention. As shown in FIG. 1, a substrate 12 made of semiconductor material is provided, in which the substrate 12 preferably includes a silicon carbide (SiC) substrate. Nevertheless, according to other embodiment of the present invention, the substrate 12 could also include a silicon substrate, an epitaxial silicon substrate, or even a silicon-on-insulator (SOI) substrate, which are all within the scope of the present invention.

Next, from bottom to top a drift region 14 is formed in the substrate 12, a first well region 16 is formed in the drift region 14 adjacent to one side such as left side of a gate structure (not shown) or a patterned gate dielectric layer 28 formed afterwards, a second well region 18 is formed in the drift region 14 adjacent to another side such as right side of the gate dielectric layer 28, a first doped region 20 and a second doped region 22 are formed in the first well region 16 adjacent to one side such as left side of the gate dielectric layer 28, a third doped region 24 and a fourth doped region 26 are formed in the second well region 18 adjacent to another side such as right side of the gate dielectric layer 28, and then a gate dielectric layer 28 is formed on the substrate 12, in which the gate dielectric layer 28 is disposed on the surface of the substrate 12 covering or overlapping the first doped region 20, the second doped region 22, the third doped region 24, and the fourth doped region 26.

In this embodiment, the drift region 14 and the first well region 16 and/or second well region 18 preferably include different conductive type, the first doped region 20 and the second doped region 22 include different conductive type, and the third doped region 24 and the fourth doped region 26 include different conductive type. For instance, the drift region 14 preferably includes a N-drift region, each of the first well region 16 and second well region 18 includes a P-well, the first doped region 20 includes a P+ doped region, the second doped region 22 includes a N+ doped region, the third doped region 24 includes a N+ doped region, and the fourth doped region 26 includes a P+ doped region.

After the first doped region 20, the second doped region 22, the third doped region 24, and the fourth doped region 26 are formed, one or more oxidation process such as in-situ steam generation (ISSG) process could be conducted to form a gate dielectric layer 28 made of silicon oxide on the surface of the substrate 12 and then a gate material layer 30 is formed on the gate dielectric layer 28, in which the gate dielectric layer 28 could be disposed to cover all surfaces of the first doped region 20, the second doped region 22, the third doped region 24, and the fourth doped region 26. In this embodiment, the gate dielectric layer 28 preferably includes silicon oxide and the gate material layer 30 includes polysilicon, but not limited thereto.

Next, as shown in FIG. 2, a photo-etching process could be conducted by using a patterned mask (not shown) such as patterned resist as mask to remove part of the gate material layer 30 and even part of the gate dielectric layer 28 through single or multiple etching processes. After stripping the patterned mask or patterned resist, gate electrodes or a first gate structure 32, a second gate structure 34, and a dummy gate 36 each made of patterned gate material layer 30 are formed on the substrate 12. In this embodiment, the dummy gate 36 is disposed between the first gate structure 32 and the second gate structure 34, the width of the first gate structure 32 is equal to the width of the second gate structure 34, the width of the dummy gate 36 is slightly less than the width of the first gate structure 32 and/or width of the second gate structure 34, and the width of the dummy gate 36 is greater than half the width of either one of the first gate structure 32 or second gate structure 34.

Next, as shown in FIG. 3, an interlayer dielectric (ILD) layer 38 is formed on the substrate 12 to cover the gate dielectric layer 28, the first gate structure 32, the second gate structure 34, and the dummy gate 36. In this embodiment, the ILD layer 38 could include silicon oxide such as tetraethyl orthosilicate (TEOS), but not limited thereto.

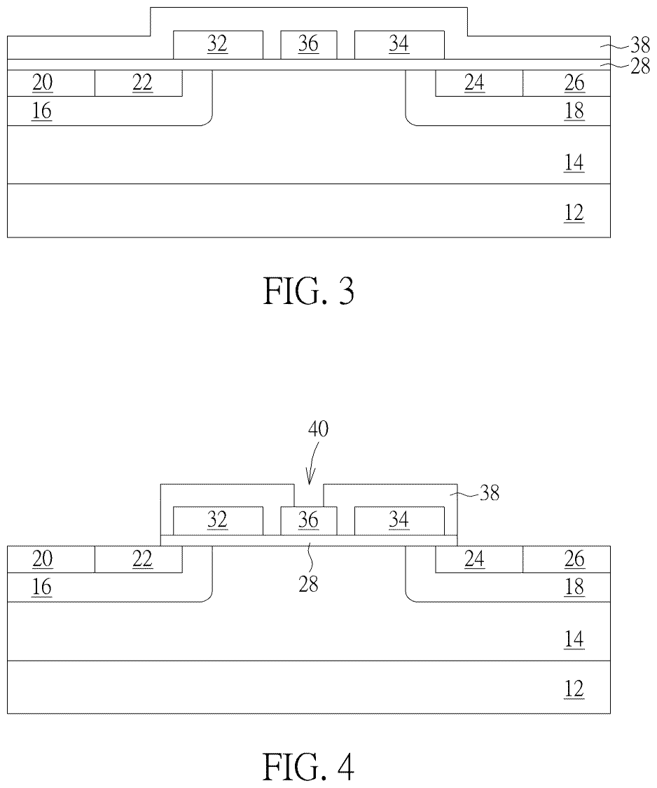

Next, as shown in FIG. 4, a photo-etching process is conducted by using a patterned mask (not shown) such as patterned resist as mask through etching to remove part of the ILD layer 38 in particular the ILD layer 38 adjacent to left side of the first gate structure 32, the ILD layer 38 adjacent to right side of the second gate structure 34, and part of the ILD layer 38 directly on top of the dummy gate 36. This forms an opening 40 exposing the top surface of the dummy gate 36 and the surface of the substrate 12 adjacent to two sides of the first gate structure 32 and second gate structure 34.

It should be noted that when part of the ILD layer 38 is removed by etching at this stage, part of the gate dielectric layer 28 adjacent to two sides of the first gate structure 32 and second gate structure 34 is removed at the same time so that sidewalls of the remaining gate dielectric layer 28 are aligned with sidewalls of the ILD layer 38 above. Nevertheless, according to other embodiment of the present invention, it would also be desirable to remove part of the gate dielectric layer 28 adjacent to two sides of the first gate structure 32 and second gate structure and even part of the gate dielectric layer 28 adjacent to two sides of the dummy gate 36 and between the first gate structure 32 and second gate structure 34 when the gate material layer 30 is patterned into the first gate structure 32, second gate structure 34, and dummy gate 36 in FIG. 2 so that the sidewalls of the remaining gate dielectric layer 28 are aligned with sidewalls of the first gate structure 32, second gate structure 34, and dummy gate 36, which is also within the scope of the present invention.

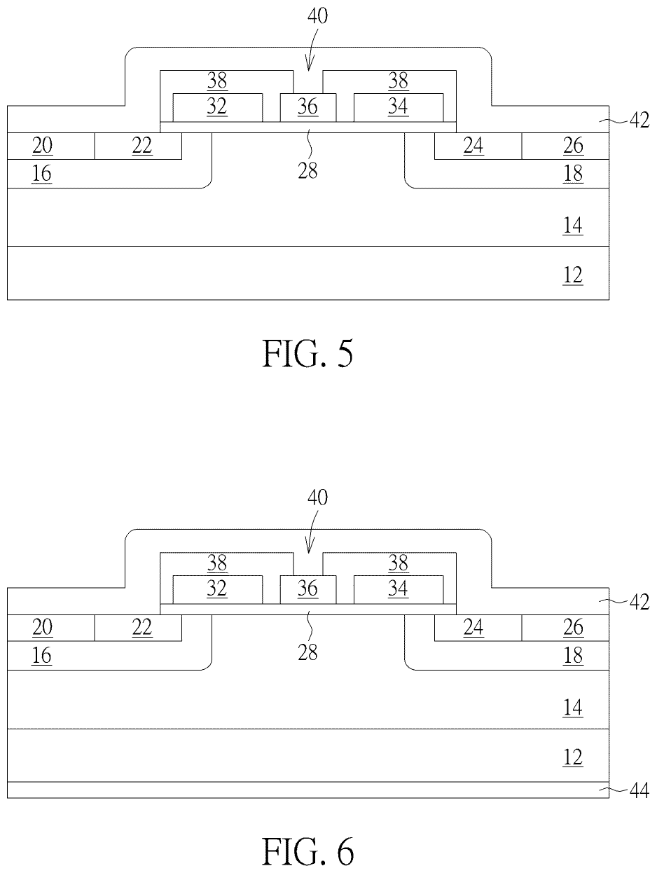

Next, as shown in FIG. 5, a source electrode 42 is formed on the ILD layer 38 and filled into the opening 40 to connect to the dummy gate 36 and doped regions adjacent to two sides of the ILD layer 38. Specifically, the source electrode 42 is formed on the top surface and sidewalls of the ILD layer 38 as well as overlapping the surface of the first doped region 20, the second doped region 22, the third doped region 24, and the fourth doped region 26 to directly contact the dummy gate 36. In this embodiment, the source electrode 42 could include conductive material or metal material such as aluminum (Al), titanium (Ti), or titanium nitride (TiN).

Next, as shown in FIG. 6, the substrate 12 could be reversed and a deposition process is conducted to form a metal layer on the backside or bottom surface of the substrate 12 serving as a drain electrode 44. In this embodiment, the drain electrode 44 and the source electrode 42 could include same material or different material. For instance, the drain electrode 44 could include conductive material or metal such as Al, Ti, or TiN. This completes the fabrication of a semiconductor device or SiC MOSFET.

Overall, the present invention discloses a SiC MOSFET and fabrication method thereof, which first forms a gate material layer 30 on the substrate, patterns the gate material layer into a first gate structure 32, a second gate structure 34, and a dummy gate 36 between the first gate structure and second gate structure, forms an ILD layer 38 on the first gate structure, second gate structure, and dummy gate, removes part of the ILD layer to form an opening 40 exposing the dummy gate, and then formed a source electrode 42 in the opening to connect to the dummy gate. According to a preferred embodiment of the present invention, the dummy gate could be serving as a field plate for the entire device such that the combination of the dummy gate and other gate structures 32, 34 on adjacent sides could effectively boost up overall balance and stability of the entire SiC MOSFET device.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method for fabricating a semiconductor device, comprising:
forming a gate material layer on a substrate;
patterning the gate material layer to form a first gate structure, a second gate structure, and a dummy gate between the first gate structure and the second gate structure;
forming an interlayer dielectric (ILD) layer on the first gate structure, the second gate structure, and the dummy gate;
forming an opening in the ILD layer to expose the dummy gate; and
forming a source electrode in the opening to connect to the dummy gate.

2. The method of claim 1, further comprising:
forming a first well region and a second well region adjacent to two sides of the first gate structure and the second gate structure;
forming a first doped region and a second doped region adjacent to one side of the first gate structure;
forming a third doped region and a fourth doped region adjacent to one side of the second gate structure;
forming a gate dielectric layer on the substrate;
forming the first gate structure, the second gate structure, and the dummy gate;
forming the ILD layer on the first gate structure, the second gate structure, and the dummy gate;
patterning the ILD layer and the gate dielectric layer;
forming the source electrode on a front side of the substrate; and
forming a drain electrode on a backside of the substrate.

3. The method of claim 2, further comprising:
forming the source electrode on the first doped region, the second doped region, the third doped region, the fourth doped region, and the ILD layer.

4. The method of claim 2, wherein the first doped region and the second doped region comprise different conductive type.

5. The method of claim 2, wherein the third doped region and the fourth doped region comprise different conductive type.

6. The method of claim 1, wherein the gate material layer comprises polysilicon.

7. A semiconductor device, comprising:
a first gate structure, a second gate structure, and a dummy gate between the first gate structure and the second gate structure on a substrate;
an interlayer dielectric (ILD) layer on the first gate structure, the second gate structure, and the dummy gate; and
a source electrode on the ILD layer and directly connected to the dummy gate.

8. The semiconductor device of claim 7, further comprising:
a first well region and a second well region adjacent to two sides of the first gate structure and the second gate structure;
a first doped region and a second doped region adjacent to one side of the first gate structure;
a third doped region and a fourth doped region adjacent to one side of the second gate structure; and
the ILD layer on the first gate structure, the second gate structure, and the dummy gate;
the source electrode on a front side of the substrate; and
a drain electrode on a backside of the substrate.

9. The semiconductor device of claim 8, wherein the source electrode overlaps the first doped region, the second doped region, the third doped region, the fourth doped region, and the ILD layer.

10. The semiconductor device of claim 8, wherein the first doped region and the second doped region comprise different conductive type.

11. The semiconductor device of claim 8, wherein the third doped region and the fourth doped region comprise different conductive type.

12. The semiconductor device of claim 7, wherein the first gate structure, the second gate structure, and the dummy gate comprise same material.

13. The semiconductor device of claim 7, wherein the first gate structure, the second gate structure, and the dummy gate comprise polysilicon.
